(19) United States
(12) Patent Application Publication
(10) Pub. No.: US 2016/0374207 A1
(43) Pub. Date: Dec. 22, 2016

(54) MULTI-RESOLUTION PRINTER

(71) Applicant: CAMTEK LTD., Migdal Haemek (IL)

(72) Inventors: Yehuda Ben-Abu, Netanya (IL); Yair Ozeri, Herzliya (IL)

(21) Appl. No.: 15/137,011

(22) Filed: Apr. 25, 2016

Related U.S. Application Data
(60) Provisional application No. 62/182,575, filed on Jun. 21, 2015.

(51) Int. Cl. H05K 3/00

(52) U.S. Cl. CPC H05K 3/0073; B41J 2/145

(57) ABSTRACT

An ink jet printer that includes a group of print heads; wherein the group of print heads comprises (a) a first sub-group of print heads that exhibit a first resolution; and (b) a second sub-group of print heads that exhibits a second resolution that differs from the first resolution; wherein in response to a printing scheme that associates a first area of a printed circuit board with the first resolution and associates a second area of the printed circuit board with the second resolution, the first sub-group is configured to print solder mask ink on the first area at the first resolution and the second sub-group is configured to print solder mask ink on the second area at the second resolution.

### BACKGROUND OF THE INVENTION

This application claims the priority of U.S. provisional patent Ser. No. 62/182,575 filing date Jun. 21, 2015 which is incorporated herein by reference.

### BACKGROUND OF THE INVENTION

Printing on printed circuit boards imposes various requirements and limitations that are un-parallel to other technological fields such as printing on paper. The inks printed on printed circuit boards during the manufacturing process must be durable and withstand very aggressive chemical etching processes. The cost of printing errors is very high.

A solder mask (www.wikipedia.org) or solder stop mask or solder resist is a thin lacquer-like layer of polymer that is usually applied to the copper traces of a printed circuit board (PCB) for protection against oxidation and to prevent solder bridges from forming between closely spaced solder pads

Printed circuit boards are printed, by solder mask printers, with solder mask ink to provide solder masks.

Solder mask printers may include one or more print heads. These one or more print heads can inkjet solder mask ink droplets of a single size.

### SUMMARY

There may be provided an ink jet printer that may include: a group of print heads; wherein the group of print heads may include (a) a first sub-group of print heads that exhibit a first resolution; and (b) a second sub-group of print heads that exhibits a second resolution that may differ from the first resolution; wherein in response to a printing scheme that associates a first area of a printed circuit board with the first resolution and associates a second area of the printed circuit board with the second resolution, the first sub-group may be configured to print solder mask ink on the first area at the first resolution and the second sub-group may be configured to print solder mask ink on the second area at the second resolution.

The first sub-group may be configured to print the solder mask ink on the first area in parallel to a printing of the solder mask ink by the second sub-group on the second area.

The first sub-group may be configured to print the solder mask ink on the first area during a first time period; wherein the second sub-group may be configured to print the solder mask ink on the second area during a second time period; wherein the first and second time periods do not overlap.

The ink jet printer may include a mechanical mechanism that may be configured to introduce a mechanical movement between the printed circuit board and the group of print heads.

The first and second areas of the printed circuit board may belong to a region of the circuit board; wherein the ink jet printer may be configured to print the solder mask ink on the first area during a first print iteration; wherein the ink jet printer may be configured to print the solder mask ink on the second area during a second print iteration; wherein during each one of the first and second print iterations a field of view of each one of the first and second sub-groups scans the region in its entirety.

Each one of the first and second sub-groups may include a same number of print heads.

The first sub-group may differ from the second sub-groups by a same number of print heads.

Print heads of the group may be arranged in an array; wherein print heads of the first sub-group may form one or more first rows of the array; wherein print heads of the second sub-group may form at least one other rows of the array.

Print heads of the group may be arranged in an array; wherein at least one row of the array may include an interleaved arrangement of print heads from the first and second sub-groups.

Print heads of the group may be arranged in an array; wherein a pair of adjacent rows of the array may include an interleaved arrangement of print heads from the first and second sub-groups.

Print heads of the group may be arranged in an array; wherein a main diagonal of the array is populated to print heads of the first sub-group and wherein entries outside the main diagonal of the array may be populated with print heads of the second sub-group.

Print heads of the group may be arranged in an array; wherein multiple diagonals of the array is populated to print heads of the first sub-group and wherein entries outside the multiple diagonals of the array may be populated with print heads of the second sub-group.

The printing scheme associates multiple first areas of the printed circuit board with the first resolution and associates multiple second areas of the printed circuit board with the second resolution, wherein in response to the printing scheme the first sub-group may be configured to print solder mask ink on the first areas at the first resolution and the second sub-group may be configured to print solder mask ink on the second areas at the second resolution.

There may be provided a method for printing solder mask ink on a printed circuit board, the method may include: in response to a printing scheme that associates a first area of a printed circuit board with a first resolution and associates a second area of the printed circuit board with a second resolution: printing by a first sub-group of print heads that exhibit a first resolution the print solder mask ink on the first area at the first resolution; and printing by a second sub-group of print heads that exhibits a second resolution that may differ from the first resolution, the print solder mask ink on the second area at the second resolution.

The printing by the first sub-group of print heads is executed in parallel to the printing by the first sub-group of print heads.

The printing by the first sub-group of print heads and the printing by the first sub-group of print heads may be executed during time periods that do not overlap.

The method may include introducing a mechanical movement, by a mechanical mechanism, between the printed circuit board and the group of print heads.

The first and second areas of the printed circuit board may belong to a region of the circuit board; wherein the method may include printing the solder mask ink on the first area during a first print iteration and printing the solder mask ink on the second area during a second print iteration; wherein during each one of the first and second print iterations a field of view of each one of the first and second sub-groups scans the region in its entirety.

The printing scheme associates multiple first areas of the printed circuit board with the first resolution and associates multiple second areas of the printed circuit board with the second resolution, wherein the method may include, in response to the printing scheme, printing by the first sub-group, solder mask ink on the first areas at the first resolution and the second sub-group may be configured to print solder mask ink on the second areas at the second resolution.

### BRIEF DESCRIPTION OF THE INVENTION

The present invention will be understood and appreciated more fully from the following detailed description taken in conjunction with the drawings in which:

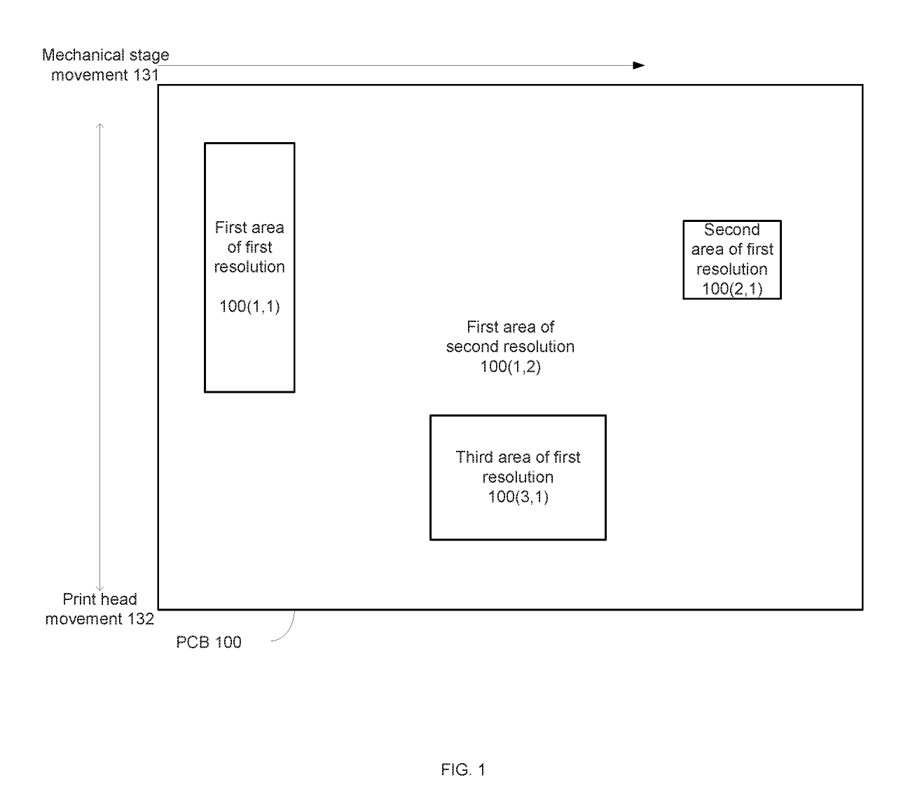

FIG. 1 illustrates a printed circuit board according to an embodiment of the invention;

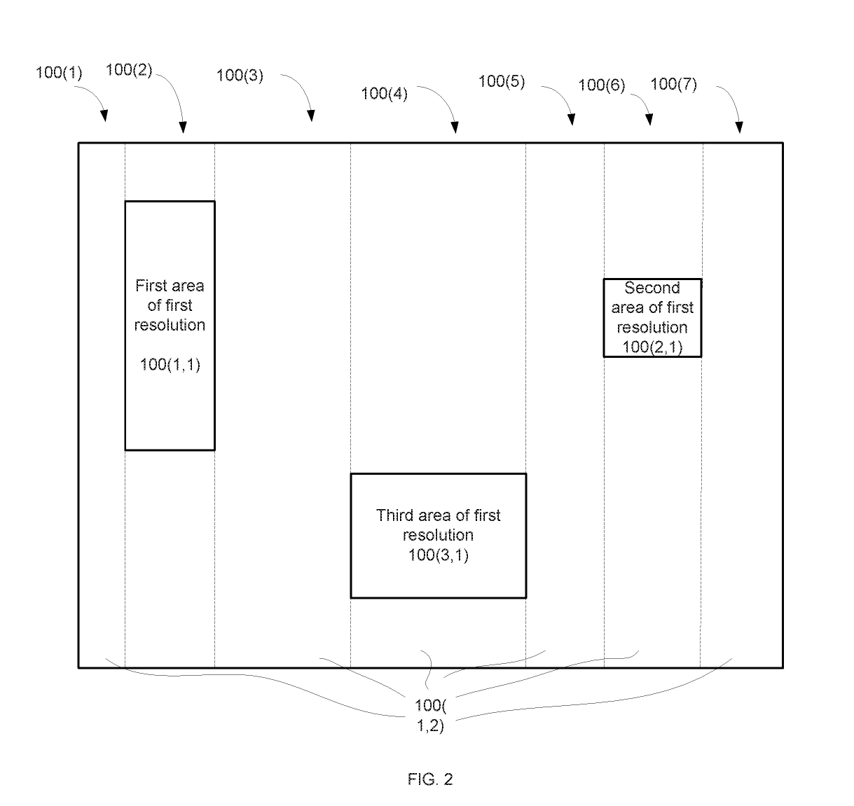

FIG. 2 illustrates a printed circuit board according to an embodiment of the invention;

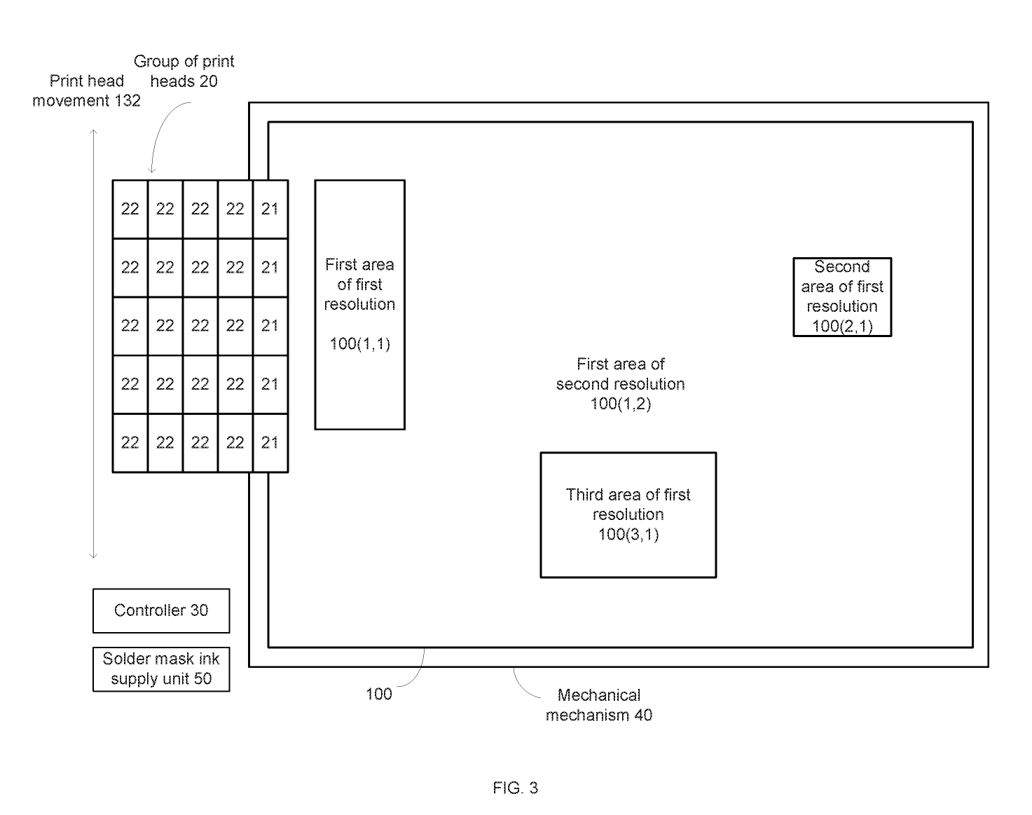

FIG. 3 illustrates a system and a printed circuit board according to an embodiment of the invention;

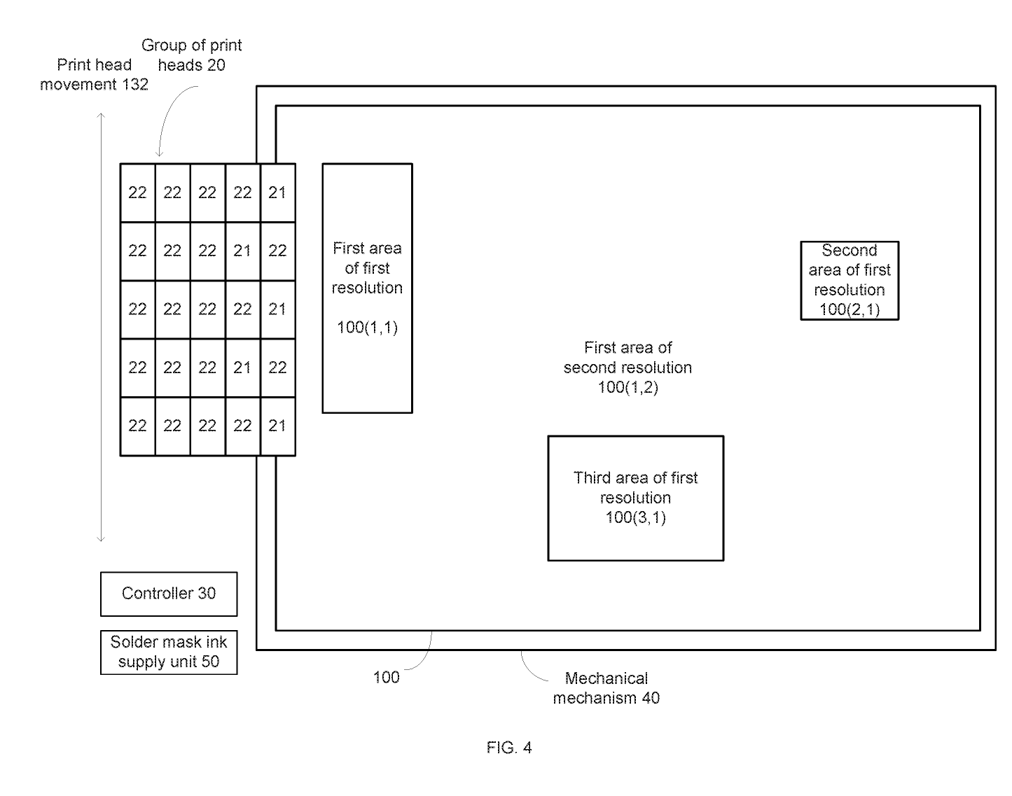

FIG. 4 illustrates a system and a printed circuit board according to an embodiment of the invention;

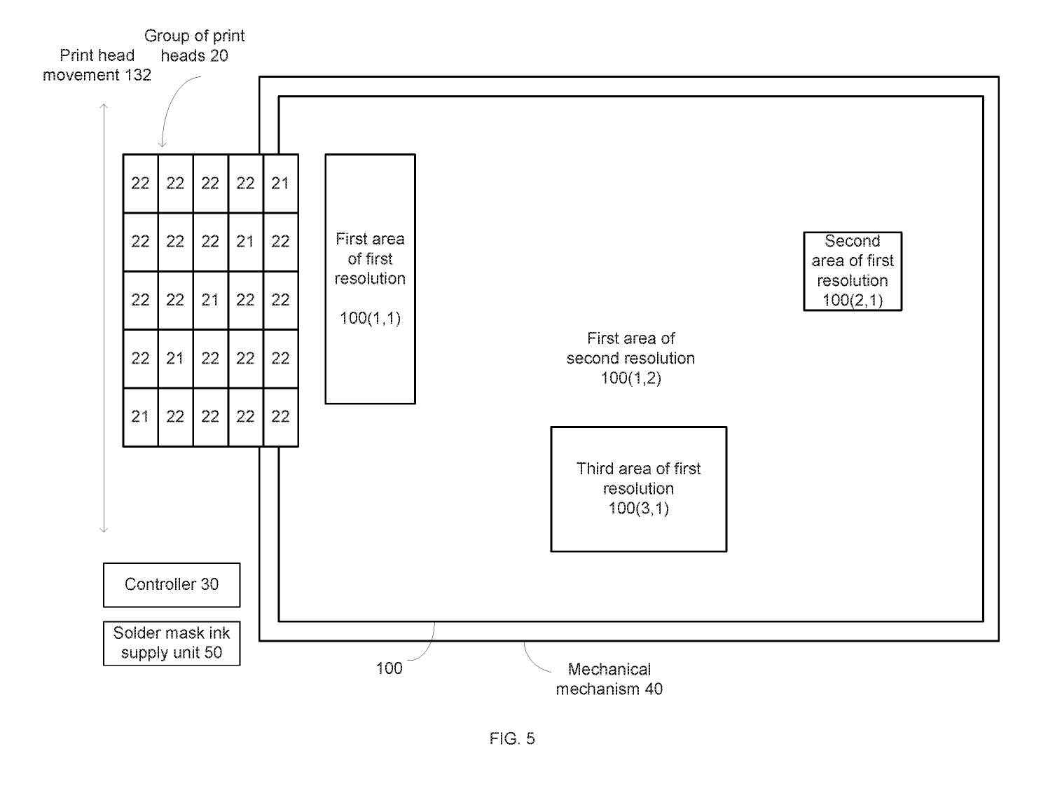

FIG. 5 illustrates a system and a printed circuit board according to an embodiment of the invention;

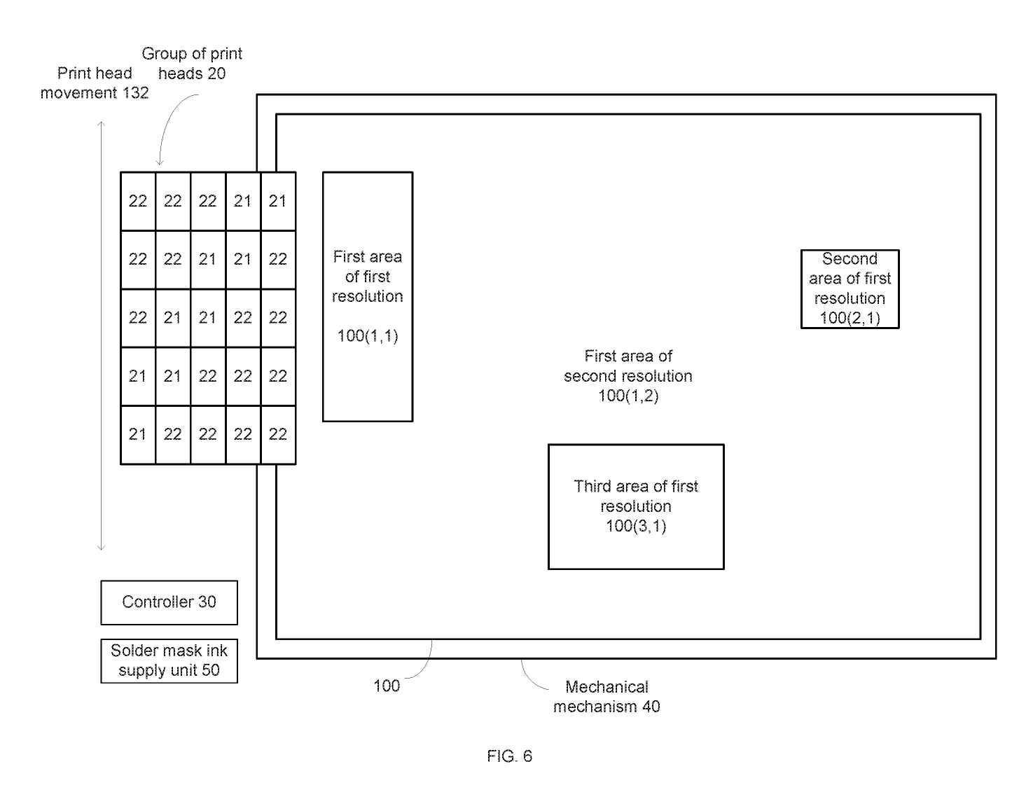

FIG. 6 illustrates a system and a printed circuit board according to an embodiment of the invention;

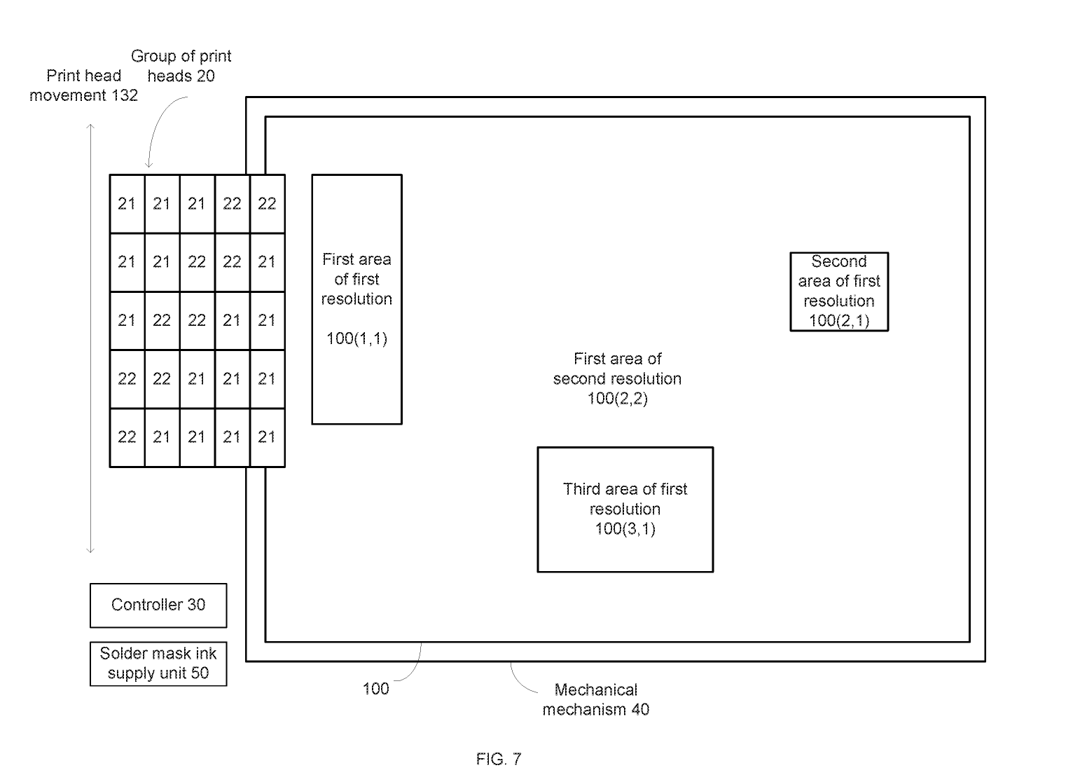

FIG. 7 illustrates a system and a printed circuit board according to an embodiment of the invention;

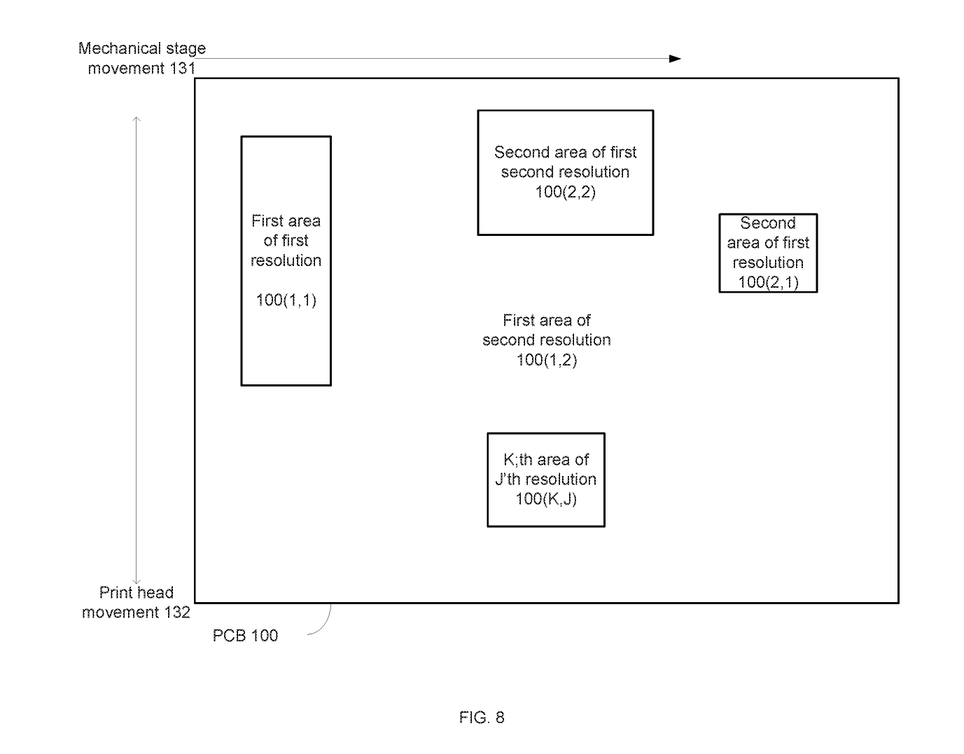

FIG. 8 illustrates a printed circuit board according to an embodiment of the invention;

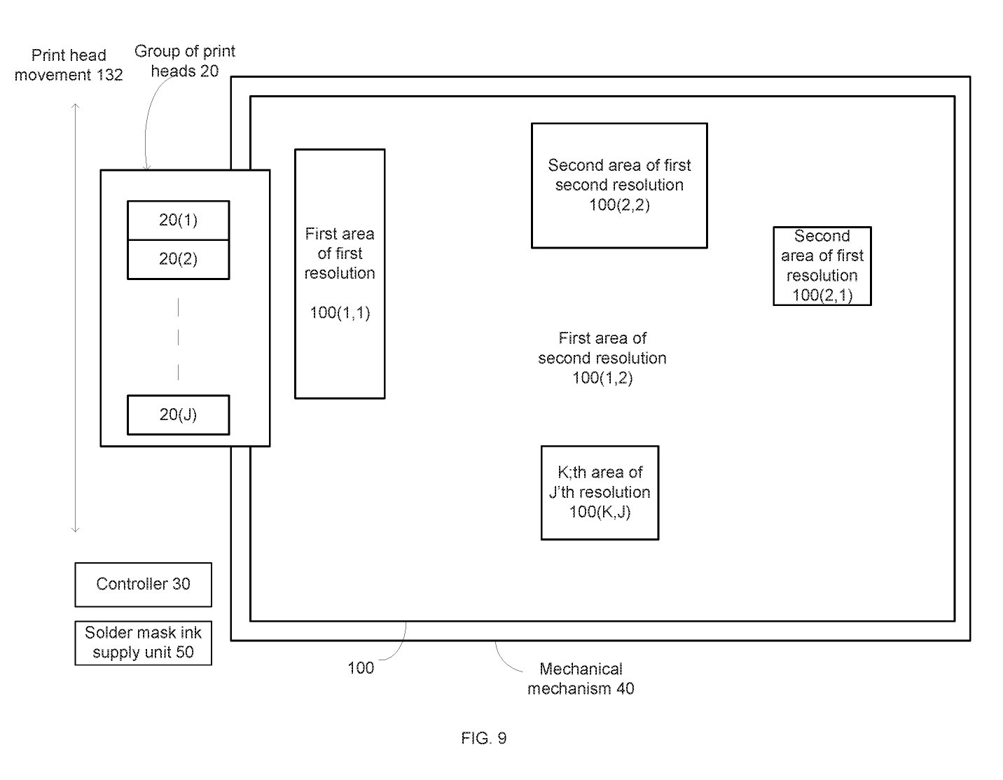

FIG. 9 illustrates a system and a printed circuit board according to an embodiment of the invention;

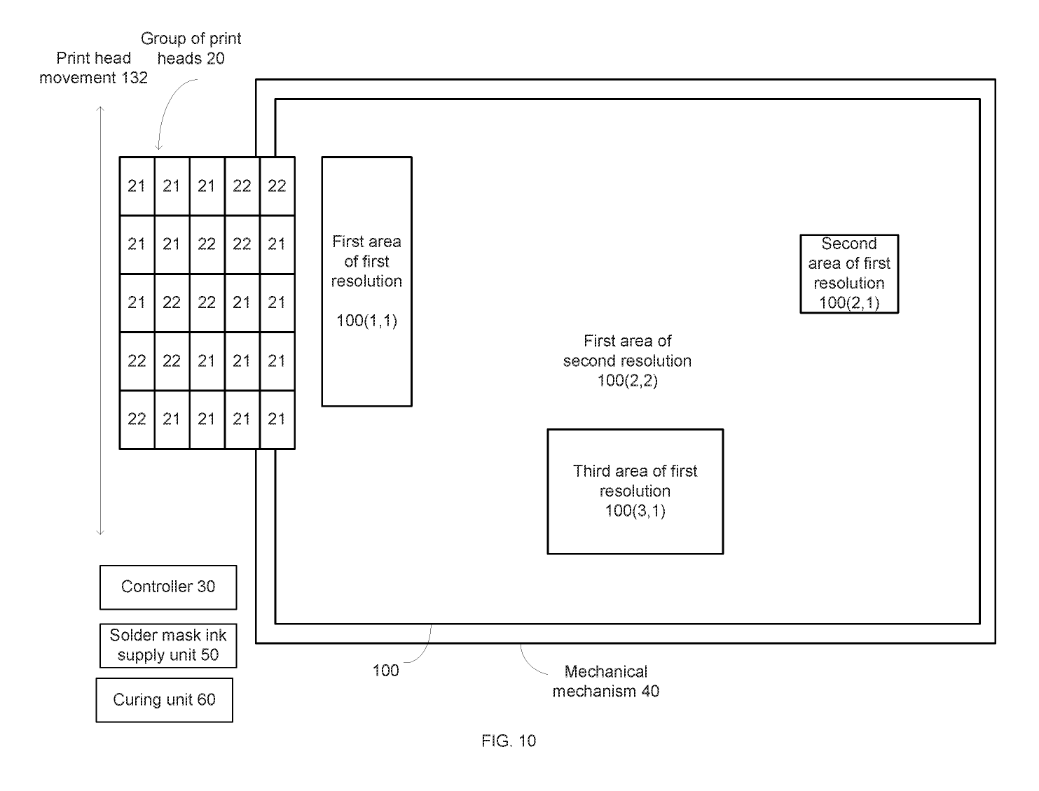

FIG. 10 illustrates a system and a printed circuit board according to an embodiment of the invention;

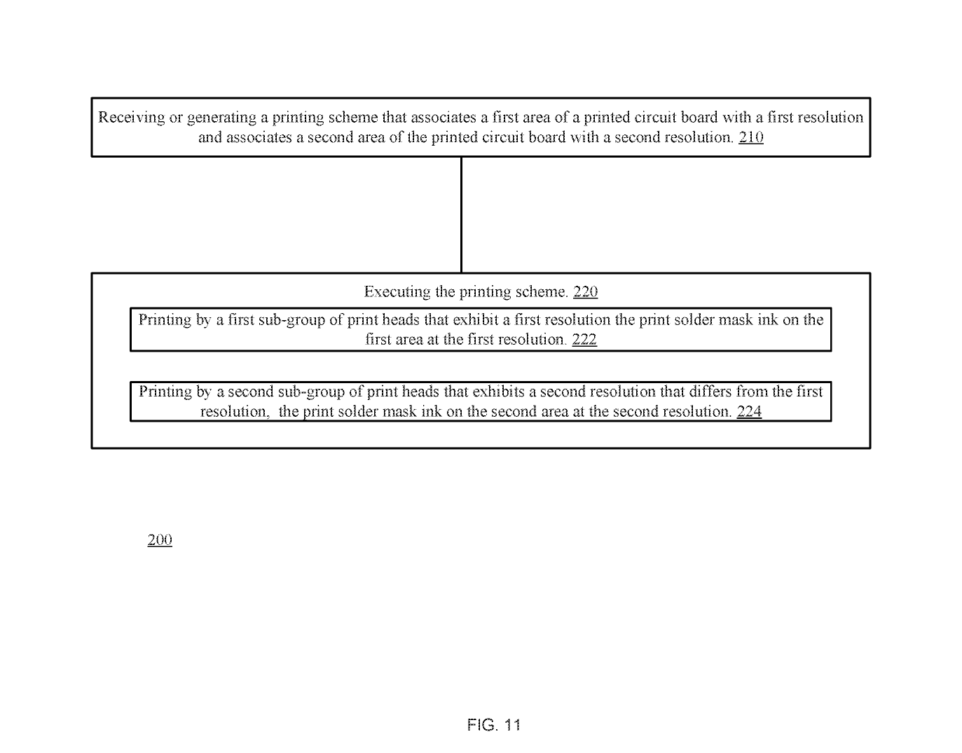

FIG. 11 illustrates a method according to an embodiment of the invention; and

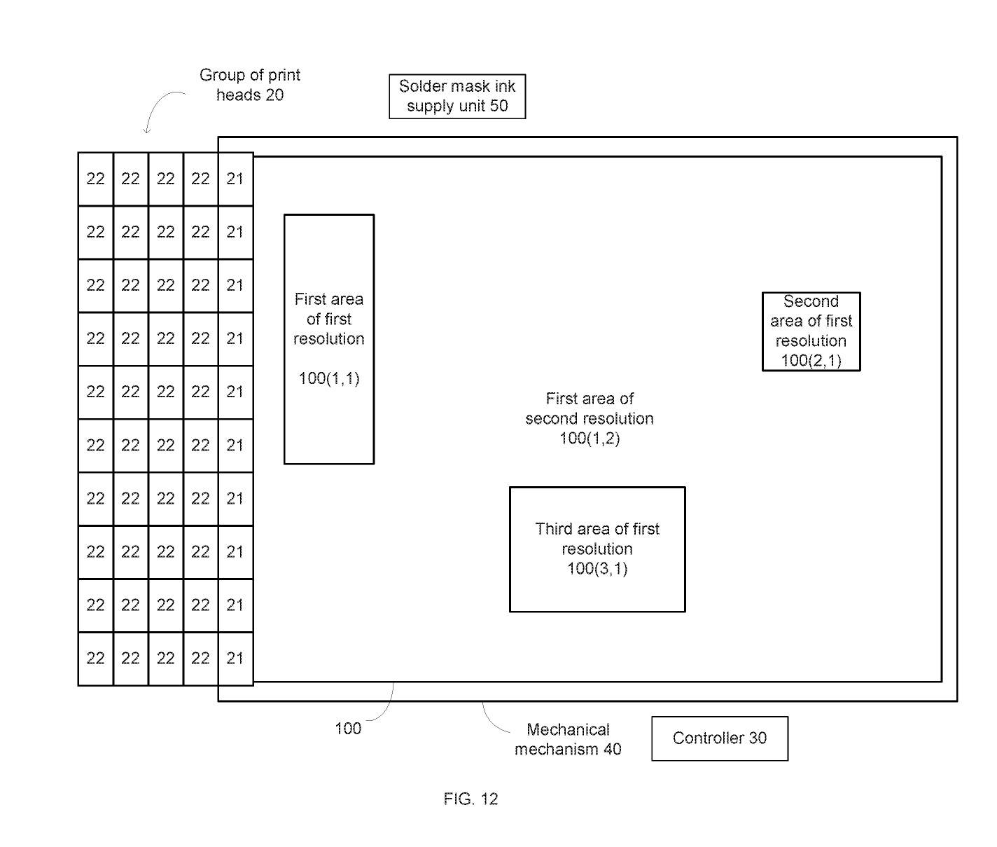

FIG. 12 illustrates a system and a printed circuit board according to an embodiment of the invention.

### DETAILED DESCRIPTION OF THE INVENTION

Because the apparatus implementing the present invention is, for the most part, composed of electronic components and circuits known to those skilled in the art, circuit details will not be explained in any greater extent than that considered necessary as illustrated above, for the understanding and appreciation of the underlying concepts of the present invention and in order not to obfuscate or distract from the teachings of the present invention.

In the following specification, the invention will be described with reference to specific examples of embodiments of the invention. It will, however, be evident that various modifications and changes may be made therein without departing from the broader spirit and scope of the invention as set forth in the appended claims.

There is provided an inkjet printer that is configured to inkjet (print) solder mask ink. The inkjet printer has a group of print heads. Different sub-groups of print heads (of the group) exhibit different resolutions. There may be two or more different sub-groups of print heads.

Some of the following examples refers to two sub-groups of print heads—a high resolution sub-group and a low resolution sub-group. Print heads of the high resolution sub-group are of higher resolution (and possibly lower throughput) than the print heads of the low resolution sub-group. Higher resolution print heads may eject smaller drops of solder mask ink.

FIG. 1 illustrates a printed circuit board (PCB) 100 that includes first area 121 of second resolution (requires printing of solder mask in at a second resolution), and first till third areas of first resolution 111, 112 and 113 (require printing of solder mask in at a first resolution).

3017/420-US

It is noted that not all of the entire areas (121, 111, 112 and 113) need to be completely covered with the solder mask but rather parts of these areas should be coated with solder mask ink to form predefined solder mask patterns.

FIG. 1 also illustrates a (X-axis) direction of mechanical stage movement 131 and a (Y-axis) print head movement 132. Typically, the two movements are required in order to “cover” PCB 100. Other movements may be applied.

FIG. 2 illustrates a virtual segmentation of the PCB 100 to slices, the virtual segmentation may correspond to the borders of the first till third areas of first resolution 111, 112 and 113. This segmentation may be relevant when printing both areas 111-113 and areas 121 at the same print iteration—especially when the movement of the group of print heads differs between printing the first till third areas of first resolution 111, 112 and 113 and when printing the first area 121 of second resolution. In segments 100(1), 100(3), 100(5) and 100(7) the movement of the group of print heads may maintained at a first value while in segments 100(2), 100(4) and 100(6) the movement may alternate between the first value and a second value—according to the locations of first till third areas of first resolution 111, 112 and 113.

FIG. 3 illustrates a PCB 100 of FIG. 1 and an inkjet printer according to an embodiment of the invention.

The inkjet printer includes a group of print heads 20, a mechanical mechanism such as a mechanical stage 40, a controller 30 for controlling the printing operations according to a printing scheme that defined areas of different resolution and a solder mask ink supply unit 50 that feeds the group of printing heads. The controller 30 may include one or more hardware processor such as general purpose processors, image processor, and the like.

The inkjet printer of any one of FIGS. 3-7 may be configured to implement a printing scheme in which one or more areas of the printed circuit board that require higher resolution may be printed with one or more high-resolution print heads and one or more areas of the printed circuit board that requires a lower resolution printing may be printed with at least one low resolution print head.

Group 20 of print heads includes a first group of print heads 21 and a second group of print heads 22.

Print heads 21 differ by resolution than print heads 22. The print heads of the different groups may also be termed high and low resolution print heads respectively—indicating that the first sub-group of print heads exhibits a higher resolution (more accurate) then the second sub-group of print heads. The print heads are configured to inkjet solder mask ink independently from each other—and according to a printing scheme.

FIGS. 3-7 illustrates different non-limiting example of the arrangement of print heads 21 and 22 according to various embodiments of the invention.

The following tables provide non-limiting arrangements of low-resolution print heads (L) and high-resolution print heads (H):

TABLE 1

| | | | | |
|---|---|---|---|---|
| H | H | H | H | H |
| L | L | L | L | L |
| L | L | L | L | L |
| L | L | L | L | L |
| L | L | L | L | L |

TABLE 2

| | | | | |
|---|---|---|---|---|
| H | L | H | L | H |
| L | H | L | H | L |
| L | L | L | L | L |
| L | L | L | L | L |
| L | L | L | L | L |

TABLE 3

| | | | | |
|---|---|---|---|---|
| H | L | L | L | L |
| L | H | L | L | L |
| L | L | H | L | L |
| L | L | L | H | L |
| L | L | L | L | H |

TABLE 4

| | | | | |
|---|---|---|---|---|
| H | L | L | L | H |
| H | H | L | L | L |
| L | H | H | L | L |
| L | L | H | H | L |
| L | L | L | H | H |

The print heads of the different sub-groups may be arranged in any manner—any spatial relationship and/or any ratio between the numbers of print heads of different sub-groups may be provided.

The printing process may involve activating multiple print heads simultaneously and/or activating only one print head at a time. High and low resolution print heads may be activated simultaneously.

In the previous texts it was assumed that there were two types or areas—of first resolution and of second resolution.

It is noted that there may me more than two different resolution levels and accordingly print heads of more than two levels of resolution. This is illustrated in FIG. 9—where there are J different levels of resolution (J is a positive integer than exceeds two). The figure also shows K area of the J'th resolution level.

It should be noted that any of the mentioned above inkjet printer may include a curing unit. FIG. 10 illustrates curing unit 60 that may be a part of the inkjet printer.

FIG. 11 illustrates a method 200 according to an embodiment of the invention.

Method 200 starts by step 210 of receiving or generating a printing scheme that associates a first area of a printed circuit board with a first resolution and associates a second area of the printed circuit board with a second resolution.

Step 210 is followed by step 220 of executing the printing scheme. Step 220 may include step 222 of printing by a first sub-group of print heads that exhibit a first resolution the print solder mask ink on the first area at the first resolution and step 224 of printing by a second sub-group of print heads that exhibits a second resolution that differs from the first resolution, the print solder mask ink on the second area at the second resolution.

FIG. 12 illustrates an inkjet printer that includes a group of print heads that “covers” the width of the PCB and thus does not perform the print head movement (denoted 132 in FIG. 1).

It is noted that the number of print heads may differ from the number illustrate din the figures, that the print heads may be arranged in a staggered array or any other array that differs from the rectangular array of FIGS. 3-7.

The print heads of the groups may be fed by the same solder mask ink.

Furthermore, those skilled in the art will recognize that boundaries between the functionality of the above described operations are merely illustrative. The functionality of multiple operations may be combined into a single operation, and/or the functionality of a single operation may be distributed in additional operations. Moreover, alternative embodiments may include multiple instances of a particular operation, and the order of operations may be altered in various other embodiments.

Thus, it is to be understood that the architectures depicted herein are merely exemplary, and that in fact many other architectures can be implemented which achieve the same functionality. In an abstract, but still definite sense, any arrangement of components to achieve the same functionality is effectively “associated” such that the desired functionality is achieved. Hence, any two components herein combined to achieve a particular functionality can be seen as “associated with” each other such that the desired functionality is achieved, irrespective of architectures or intermedial components. Likewise, any two components so associated can also be viewed as being “operably connected,” or “operably coupled,” to each other to achieve the desired functionality.

However, other modifications, variations, and alternatives are also possible. The specifications and drawings are, accordingly, to be regarded in an illustrative rather than in a restrictive sense.

The word “comprising” does not exclude the presence of other elements or steps then those listed in a claim. It is understood that the terms so used are interchangeable under appropriate circumstances such that the embodiments of the invention described herein are, for example, capable of operation in other orientations than those illustrated or otherwise described herein.

Furthermore, the terms “a” or “an,” as used herein, are defined as one or more than one. Also, the use of introductory phrases such as “at least one” and “one or more” in the claims should not be construed to imply that the introduction of another claim element by the indefinite articles “a” or “an” limits any particular claim containing such introduced claim element to inventions containing only one such element, even when the same claim includes the introductory phrases “one or more” or “at least one” and indefinite articles such as “a” or “an.” The same holds true for the use of definite articles. Unless stated otherwise, terms such as “first” and “second” are used to arbitrarily distinguish between the elements such terms describe.

Thus, these terms are not necessarily intended to indicate temporal or other prioritization of such elements. The mere fact that certain measures are recited in mutually different claims does not indicate that a combination of these measures cannot be used to advantage.

We claim:

1. An ink jet printer that comprises: a group of print heads; wherein the group of print heads comprises (a) a first sub-group of print heads that exhibit a first resolution;
and (b) a second sub-group of print heads that exhibits a second resolution that differs from the first resolution; wherein in response to a printing scheme that associates a first area of a printed circuit board with the first resolution and associates a second area of the printed circuit board with the second resolution, the first sub-group is configured to print solder mask ink on the first area at the first resolution and the second sub-group is configured to print solder mask ink on the second area at the second resolution.

2. The ink jet printer according to claim 1 wherein the first sub-group is configured to print the solder mask ink on the first area in parallel to a printing of the solder mask ink by the second sub-group on the second area.

3. The ink jet printer according to claim 1 wherein the first sub-group is configured to print the solder mask ink on the first area during a first time period; wherein the second sub-group is configured to print the solder mask ink on the second area during a second time period; wherein the first and second time periods do not overlap.

4. The ink jet printer according to claim 1 comprising a mechanical mechanism that is configured to introduce a mechanical movement between the printed circuit board and the group of print heads.

5. The ink jet printer according to claim 4; wherein the first and second areas of the printed circuit board belong to a region of the circuit board; wherein the ink jet printer is configured to print the solder mask ink on the first area during a first print iteration;
wherein the ink jet printer is configured to print the solder mask ink on the second area during a second print iteration; wherein during each one of the first and second print iterations a field of view of each one of the first and second sub-groups scans the region in its entirety.

6. The ink jet printer according to claim 1 each one of the first and second sub-groups comprises a same number of print heads.

7. The ink jet printer according to claim 1 the first sub-group differs from the second sub-groups by a same number of print heads.

8. The ink jet according to claim 1 wherein print heads of the group are arranged in an array; wherein print heads of the first sub-group form one or more first rows of the array; wherein print heads of the second sub-group form at least one other rows of the array.

9. The ink jet according to claim 1 wherein print heads of the group are arranged in an array; wherein at least one row of the array comprises an interleaved arrangement of print heads from the first and second sub-groups.

10. The ink jet according to claim 1 wherein print heads of the group are arranged in an array; wherein a pair of adjacent rows of the array comprise an interleaved arrangement of print heads from the first and second sub-groups.

11. The ink jet according to claim 1 wherein print heads of the group are arranged in an array; wherein a main diagonal of the array is populated to print heads of the first sub-group and wherein entries outside the main diagonal of the array are populated with print heads of the second sub-group.

12. The ink jet according to claim 1 wherein print heads of the group are arranged in an array; wherein multiple diagonals of the array is populated to print heads of the first sub-group and wherein entries outside the multiple diagonals of the array are populated with print heads of the second sub-group.

13. The ink jet according to claim 1, wherein the printing scheme associates multiple first areas of the printed circuit board with the first resolution and associates multiple second areas of the printed circuit board with the second resolution, wherein in response to the printing scheme the first sub-group is configured to print solder mask ink on the first areas at the first resolution and the second sub-group is configured to print solder mask ink on the second areas at the second resolution.

14. A method for printing solder mask ink on a printed circuit board, the method comprises: in response to a printing scheme that associates a first area of a printed circuit board with a first resolution and associates a second area of the printed circuit board with a second resolution: printing by a first sub-group of print heads that exhibit a first resolution the print solder mask ink on the first area at the first resolution; and printing by a second sub-group of print heads that exhibits a second resolution that differs from the first resolution, the print solder mask ink on the second area at the second resolution.

15. The method according to claim 14 wherein the printing by the first sub-group of print heads is executed in parallel to the printing by the first sub-group of print heads.

16. The method according to claim 14 wherein the printing by the first sub-group of print heads and the printing by the first sub-group of print heads are executed during time periods that do not overlap.

17. The method according to claim 14 comprising introducing a mechanical movement, by a mechanical mechanism, between the printed circuit board and the group of print heads.

18. The method according to claim 17, wherein the first and second areas of the printed circuit board belong to a region of the circuit board; wherein the method comprises printing the solder mask ink on the first area during a first print iteration and printing the solder mask ink on the second area during a second print iteration; wherein during each one of the first and second print iterations a field of view of each one of the first and second sub-groups scans the region in its entirety.

19. The method according to claim 14, wherein each one of the first and second sub-groups comprises a same number of print heads.

20. The method according to claim 14, wherein the first sub-group differs from the second sub-groups by a same number of print heads.

21. The method according to claim 14 wherein print heads of the group are arranged in an array; wherein print heads of the first sub-group form one or more first rows of the array; wherein print heads of the second sub-group form at least one other rows of the array.

22. The method according to claim 14 wherein print heads of the group are arranged in an array; wherein at least one row of the array comprises an interleaved arrangement of print heads from the first and second sub-groups.

23. The method according to claim 14 wherein print heads of the group are arranged in an array; wherein a pair of adjacent rows of the array comprise an interleaved arrangement of print heads from the first and second sub-groups.

24. The method according to claim 14 wherein print heads of the group are arranged in an array; wherein a main diagonal of the array is populated to print heads of the first sub-group and wherein entries outside the main diagonal of the array are populated with print heads of the second sub-group.

25. The method according to claim 14 wherein print heads of the group are arranged in an array; wherein multiple diagonals of the array is populated to print heads of the first sub-group and wherein entries outside the multiple diagonals of the array are populated with print heads of the second sub-group.

26. The method according to claim 14, wherein the printing scheme associates multiple first areas of the printed circuit board with the first resolution and associates multiple second areas of the printed circuit board with the second resolution, wherein in response to the printing scheme the first sub-group is configured to print solder mask ink on the first areas at the first resolution and the second sub-group is configured to print solder mask ink on the second areas at the second resolution.
